(19) United States
(12) Patent Application Publication
(10) Pub. No.: US 2025/0246928 A1
(43) Pub. Date: Jul. 31, 2025

(54) APPARATUS AND METHOD FOR MANAGING BATTERY

(71) Applicants: Hyundai Motor Company, Seoul (KR); Kia Corporation, Seoul (KR)

(72) Inventors: Yoo Hong JANG, Suwon-Si (KR); Yo Han BAEK, Anyang-Si (KR); Sang Jin LEE, Goyang-Si (KR); Hyo Kyung LEE, Anyang-Si (KR); Bo Hyun LEE, Incheon (KR)

(73) Assignees: Hyundai Motor Company, Seoul (KR); Kia Corporation, Seoul (KR)

(21) Appl. No.: 18/900,356

(22) Filed: Sep. 27, 2024

(30) Foreign Application Priority Data
Jan. 26, 2024 (KR) 10-2024-0012600

(51) Int. Cl. H02J 7/00; B60L 53/10; H01M 10/44; H01M 50/51

(52) U.S. Cl. CPC H02J 7/007182; B60L 53/11; H01M 10/441; H01M 50/51

(57) ABSTRACT

In an apparatus for managing a battery and a method thereof, the apparatus includes an charger that charges the battery including two or more battery cells connected in series, and a processor that is configured to control the charger to charge the battery with a first constant current in response to a fast charging request for the battery, monitors one of voltages of the battery cells while fast charging is in progress, and is configured to control charging characteristics of the battery according to a section in a dQ/dV profile to which the cell voltage belongs.

### CROSS-REFERENCE TO RELATED APPLICATION

The present application claims priority to Korean Patent Application No. 10-2024-0012600, filed on Jan. 26, 2024, the entire contents of which is incorporated herein for all purposes by this reference.

### BACKGROUND OF THE INVENTION

### Field of the Present Disclosure

The present disclosure relates to an apparatus for managing a battery and a method thereof, and more particularly, to a technology for charging a battery and diagnosing an abnormality of a battery.

### Description of Related Art

Due to the diversity of electronic devices, the field of use of batteries has increased, and recently, the use of batteries has increased as electric vehicles such as electric vehicles or hybrid vehicles are introduced.

While battery usage time increases, battery capacity limitations are not easily overcome, and battery charging problems emerge. A fast charging scheme is widely used to rapidly charge a battery, but as the charging speed increases, the durability of the battery decreases.

Furthermore, the slow charging speed of the battery to prevent the durability of the battery from deteriorating may cause inconvenience to a user.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing an apparatus for managing a battery that does not reduce the durability of the battery without reducing the charging speed of the battery, and a method thereof.

Furthermore, another aspect of the present disclosure provides an apparatus for managing a battery configured for diagnosing an abnormality of the battery based on battery charging characteristics, and a method thereof.

The technical problems to be solved by the present disclosure are not limited to the aforementioned problems, and any other technical problems not mentioned herein will be clearly understood from the following description by those skilled in the art to which the present disclosure pertains.

According to an aspect of the present disclosure, an apparatus for managing a battery includes an charger that charges the battery including two or more battery cells connected in series, and a processor that is configured to control the charger to charge the battery with a first constant current in response to a fast charging request for the battery, monitors one of voltages of the battery cells while fast charging is in progress, and is configured to control charging characteristics of the battery according to a section in a dQ/dV profile to which the cell voltage belongs.

According to an exemplary embodiment of the present disclosure, the processor is configured to determine whether the cell voltage reaches a phase transition section of the dQ/dV profile in a section where the fast charging is in progress, and control the charger to charge the battery at a constant voltage in the phase transition section.

According to an exemplary embodiment of the present disclosure, the processor is configured to determine a voltage section including the cell voltage corresponding to a peak in the dQ/dV profile as the phase transition section.

According to an exemplary embodiment of the present disclosure, the processor may identify a maximum cell voltage at an entry timing of the phase transition section, and determine the maximum cell voltage as a magnitude of the constant voltage.

According to an exemplary embodiment of the present disclosure, the processor is configured for controlling the charger to charge the battery based on a second constant current after the phase transition section.

According to an exemplary embodiment of the present disclosure, the processor may identify a cut-off current corresponding to a current of the battery at an end timing of the phase transition section, and determine a magnitude of the second constant current within a range greater than or equal to the cut-off current and less than or equal to the first constant current.

According to an exemplary embodiment of the present disclosure, the processor may identify a battery cell showing a maximum cell voltage in response to a slow charging request, obtain a reference dQ/dV profile for a battery cell showing the maximum cell voltage, and update the dQ/dV profile based on the reference dQ/dV profile.

According to an exemplary embodiment of the present disclosure, the processor may exclude an update procedure of the phase transition section when a remaining capacity of the battery is greater than a reference remaining capacity.

According to an exemplary embodiment of the present disclosure, the processor may obtain the reference dQ/dV profile including a plurality of peaks, obtain an average dQ/dV profile based on average voltages of the battery cells, and determine whether the battery is in an abnormal state based on a decrease amount of the peaks of the reference dQ/dV profile compared to peaks of the average dQ/dV profile.

According to an exemplary embodiment of the present disclosure, the processor is configured to determine that the battery is in an abnormal state based on a total decrease amount of the peaks of each reference dQ/dV profile compared to the peaks of each average dQ/dV profile being greater than or equal to a first threshold.

According to an exemplary embodiment of the present disclosure, the processor is configured to determine that the battery is in an abnormal state based on at least one of decrease amounts of the peaks of the reference dQ/dV profile compared to the peaks of the average dQ/dV profile being greater than or equal to a second threshold.

According to an exemplary embodiment of the present disclosure, the processor is configured to determine whether the battery is in the abnormal state based on voltages matching the peaks of the reference dQ/dV profile compared to voltages matching the peaks of the average dQ/dV profile.

According to another aspect of the present disclosure, a method of managing a battery may controlling a charger to charge the battery with a first constant current in response to a fast charging request for the battery including a plurality of battery cells, monitoring one of voltages of the battery cells while fast charging is in progress, and controlling charging characteristics of the battery according to a section in a dQ/dV profile to which the cell voltage belongs.

According to an exemplary embodiment of the present disclosure, the controlling of the charging characteristics may include determining whether the cell voltage is included in a phase transition section of the dQ/dV profile, and controlling the charger to charge the battery at a constant voltage in the phase transition section.

According to an exemplary embodiment of the present disclosure, the controlling of the charger in the phase transition section may include identifying a maximum cell voltage at an entry timing of the phase transition section, and determining the maximum cell voltage as a magnitude of the constant voltage.

According to an exemplary embodiment of the present disclosure, the method may further include charging the battery based on a second constant current after the phase transition section.

According to an exemplary embodiment of the present disclosure, the charging of the battery based on the second constant current may include identifying a cut-off current corresponding to a current of the battery at an end timing of the phase transition section, and determining a magnitude of the second constant current within a range greater than or equal to the cut-off current and less than or equal to the first constant current.

According to an exemplary embodiment of the present disclosure, the method may further include identifying a battery cell showing a maximum cell voltage in response to a slow charging request, obtaining a reference dQ/dV profile for a battery cell showing the maximum cell voltage, and updating the dQ/dV profile based on the reference dQ/dV profile.

According to an exemplary embodiment of the present disclosure, the method may further include detecting peaks in the reference dQ/dV profile, obtaining an average dQ/dV profile based on average voltages of the battery cells, and determining whether the battery is in an abnormal state based on a decrease amount of the peaks of the reference dQ/dV profile compared to peaks of the average dQ/dV profile.

According to an exemplary embodiment of the present disclosure, wherein the determining of whether the battery is in the abnormal state may include determining whether the battery is in the abnormal state based on voltages matching the peaks of the reference dQ/dV profile compared to voltages matching the peaks of the average dQ/dV profile.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a block diagram illustrating the connection relationship of an apparatus for managing a battery according to an exemplary embodiment of the present disclosure;

FIG. 2 is a block diagram illustrating the configuration of an apparatus for managing a battery according to an exemplary embodiment of the present disclosure;

FIG. 3 is a diagram illustrating an example of a dQ/dV profile;

FIG. 4 is a flowchart illustrating a method of managing a battery according to an exemplary embodiment of the present disclosure;

FIG. 5 is a diagram illustrating a battery charging scheme according to an exemplary embodiment of the present disclosure and the voltage of a battery cell according to the battery charging scheme.

FIG. 6 is a diagram illustrating the current change of the battery cell during a battery charging process according to an exemplary embodiment of the present disclosure;

FIG. 7 is a diagram illustrating the voltage change of a battery cell during a battery charging process according to an exemplary embodiment of the present disclosure;

FIG. 8 is a diagram illustrating the change in durability of a battery cell according to an exemplary embodiment of the present disclosure;

FIG. 9 is a flowchart illustrating a method of managing a battery according to another exemplary embodiment of the present disclosure;

FIG. 10 is a flowchart illustrating a method of diagnosing an abnormality of a battery according to an exemplary embodiment of the present disclosure; and

FIG. 11 is a block diagram illustrating a computing system according to an exemplary embodiment of the present disclosure.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, various exemplary embodiments of the present disclosure will be described in detail with reference to the exemplary drawings. In adding the reference numerals to the components of each drawing, it should be noted that the identical or equivalent component is designated by the identical numeral even when they are displayed on other drawings. Furthermore, in describing the exemplary embodiment of the present disclosure, a detailed description of the related known configuration or function will be omitted when it is determined that it interferes with the understanding of the exemplary embodiment of the present disclosure.

In describing the components of the exemplary embodiment of the present disclosure, terms such as first, second, A, B, (a), (b), and the like may be used. These terms are merely intended to distinguish the components from other components, and the terms do not limit the nature, order or sequence of the components. Unless otherwise defined, all terms including technical and scientific terms used herein include the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless so defined herein.

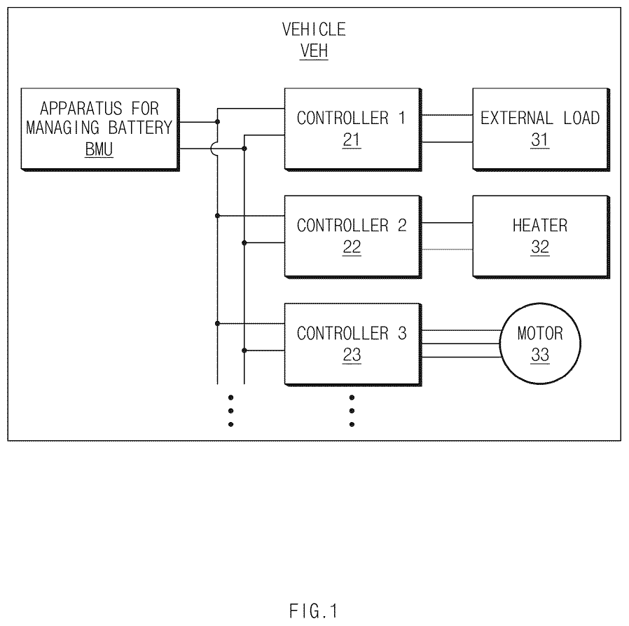

Hereinafter, various exemplary embodiments of the present disclosure will be described in detail with reference to FIGS. 1 to 11.

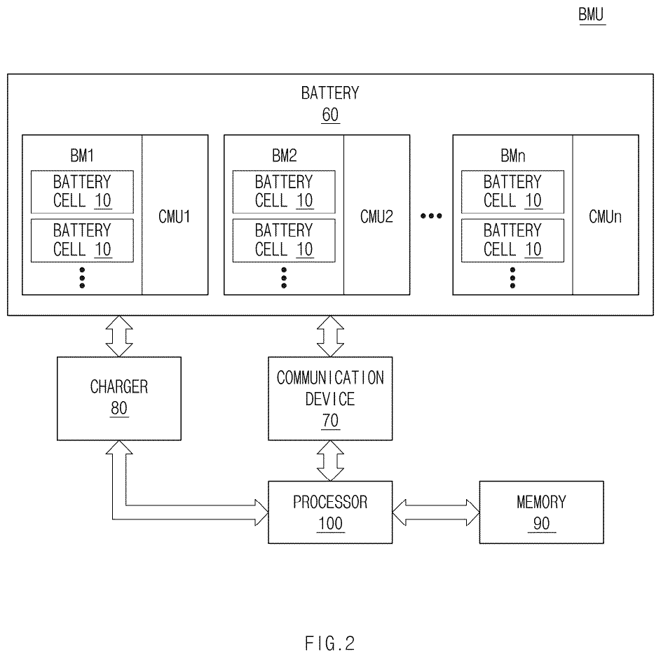

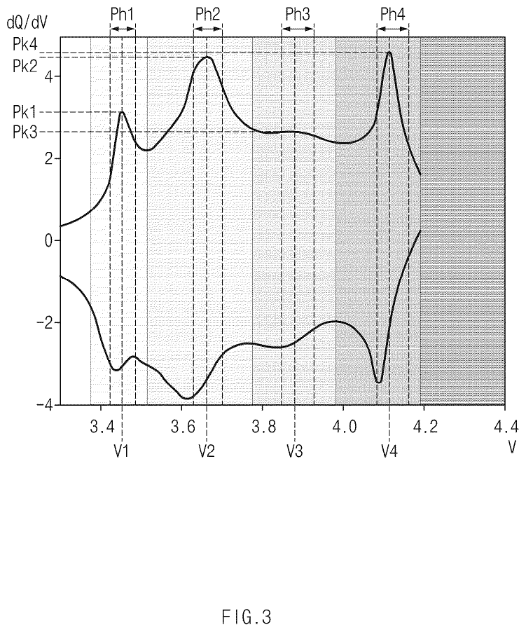

FIG. 1 is a block diagram illustrating the connection relationship of an apparatus for managing a battery according to an exemplary embodiment of the present disclosure. FIG. 2 is a block diagram illustrating the configuration of an apparatus for managing a battery according to an exemplary embodiment of the present disclosure. FIG. 3 is a diagram illustrating an example of a dQ/dV profile.

Hereinafter, an apparatus for managing a battery according to an exemplary embodiment of the present disclosure will be described with reference to FIG. 1, FIG. 2, and FIG. 3.

Referring to FIG. 1, an apparatus BMU for managing a battery according to an exemplary embodiment of the present disclosure may be mounted on a vehicle VEH and provide a voltage to controllers 21, 22, and 23 within the vehicle. For example, the first controller 21 may provide a voltage to an external load 31. The second controller 22 may include a DC/DC converter for providing a voltage to a heater 32. The third controller 23 may include a DC/AC converter for providing a voltage to a motor 33 that drives the vehicle.

To the present end, as shown in FIG. 2, the apparatus BMU for managing a battery according to an exemplary embodiment of the present disclosure may include a battery 60, a communication device 70, sensor devices CMU1 to CMUn, and a processor 100.

The battery 60 may include n (n is a natural number of 2 or more) battery modules BM1 to BMn. Each of the battery modules BM1 to BMn may include a plurality of battery cells 10.

The sensor devices CMU1 to CMUn may be implemented as cell monitoring units with one-to-one correspondence to the battery modules BM1 to BMn. The first CMU CMU1 may detect the voltage of the first battery module BM1. Furthermore, the sensor devices CMU1 to CMUn may obtain battery state information.

The communication device 70, which is for communication between the sensor devices CMU1 to CMUn and the processor 100, may be implemented with a wired or wireless communication device.

For example, the communication device 70 may support short-range communication by use of at least one of Bluetooth™, radio frequency identification (RFID), infrared data association (IrDA), ultra wideband (UWB), ZigBee, Near Field Communication (NFC), Wireless-Fidelity (Wi-Fi), Wi-Fi Direct, and wireless universal serial bus (USB) technology.

Furthermore, when the processor 100 is located outside a vehicle, the communication device 70 may perform communication based on Global System for Mobile communication (GSM), Code Division Multi Access (CDMA), code division multi access 2000 (CDMA2000), enhanced voice-data optimized or enhanced voice-data only (EV-DO), Wideband CDMA (WCDMA), High Speed Downlink Packet Access (HSDPA), High Speed Uplink Packet Access (HSUPA), Long Term Evolution (LTE), Long Term Evolution-Advanced (LTE-A), and the like.

A charger 80 may be used to charge the battery 60 and may include a fast charger and a slow charger. The fast charger may rapidly charge the battery 60 by supplying direct current power directly to a charging plug of a vehicle. The slow charger may be an on-board charger (OBC) that converts alternating current power supplied through a charging plug of a vehicle into direct current power and supplies the direct current power to the battery 60.

The processor 100 may identify the charging request for the battery 60 and control the charger 80 according to the charging request. The processor 100 may alternately perform constant current charging and constant voltage charging in response to a fast charging request. In a process of performing constant current charging, the processor 100 may monitor one of cell voltages of the battery 60, and control the charging characteristics of the battery 60 according to the section to which the cell voltage belongs in the dQ/dV profile. For example, the processor 100 may charge the battery 60 in a constant voltage charging scheme in response to the cell voltage of the battery 60 reaching the phase transition section in the dQ/dV profile.

As shown in FIG. 3, the dQ/dV profile may be a graph showing voltage (V) according to dQ/dV and may be referred to as a differential capacitance characteristic curve. FIG. 3 may show a dQ/dV profile of a ternary cathode material (NMC) battery containing nickel, manganese, and cobalt as main components.

The dQ/dV may be a value obtained by differentiating the charging capacity of the battery cell 10 by the voltage of the battery cell 10. The dQ/dV profile may match dQ/dV with the voltage of the battery cell 10.

The dQ/dV profile of the battery cell 10 may include phase transition sections Ph1, Ph2, Ph3, and Ph4 in which the phase changes. The first phase transition section Ph1 may be a section in which C₆ transitions to LiCₓ. The second phase transition section Ph2, which is a phase transition section of NMC, may be a section in which a hexagonal structure changes into a monoclinic structure. The third phase transition section Ph3 may be a section in which H₂ changes into a phase of H₃. In an NMC battery, the fourth phase transition section Ph4 may be a stabilization section.

In the dQ/dV profile, the first, second, third and fourth phase transition sections Ph1, Ph2, Ph3, and Ph4 may be sections including voltages that generate peaks. For example, the first phase transition section Ph1 may be a voltage section including a first voltage V1 that generates a first peak Pk1. The second phase transition section Ph2 may be a voltage section including a second voltage V2 that generates a second peak Pk2, and the third phase transition section Ph3 may be a voltage section including a third voltage V3 that generates a third peak Pk3. The fourth phase transition section Ph4 may be a voltage section including a fourth voltage V4 that generates a fourth peak Pk4.

The dQ/dV profile may be determined in advance based on the battery cell 10 before deterioration.

The algorithm for operating the processor 100 may be stored in a memory 90. The memory 90 may include a hard disk drive, a flash memory, an electrically erasable programmable read-only memory (EEPROM), a static RAM (SRAM), a ferro-electric RAM (FRAM), a phase-change RAM (PRAM), a magnetic RAM (MRAM), a dynamic random access memory (DRAM), a synchronous dynamic random access memory (SDRAM), a double date rate-SDRAM (DDR-SDRAM), and the like.

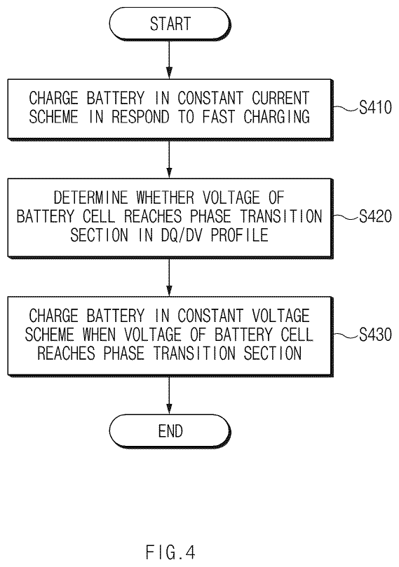

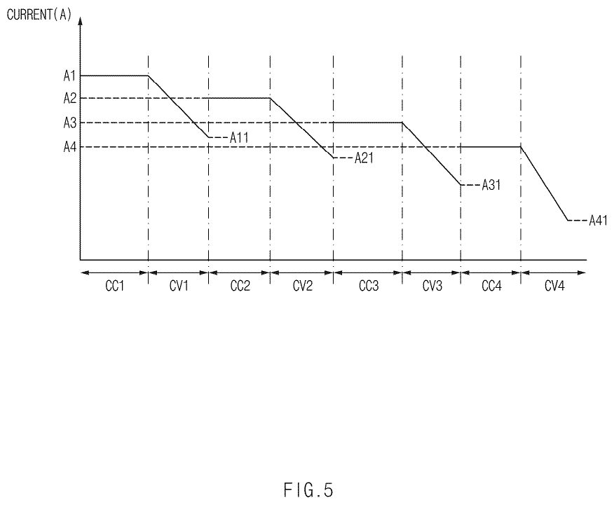

FIG. 4 is a flowchart illustrating a method of managing a battery according to an exemplary embodiment of the present disclosure. FIG. 5 is a diagram illustrating a battery charging scheme according to an exemplary embodiment of the present disclosure and the voltage of a battery cell according to the battery charging scheme. FIG. 4 illustrates procedures controlled by the processor shown in FIG. 2. A method of managing a battery according to an exemplary embodiment of the present disclosure will be described below with reference to FIG. 2, FIG. 3, FIG. 4 and FIG. 5.

In operation S410, the processor 100 may be configured for controlling the battery 60 to be charged with a first constant current A1 in respond to the fast charging request for the battery 60.

Operation S410 may correspond to a first constant current charging section CC1.

The first constant current A1 may be set in advance and may be determined based on the battery cell 10 in a non-deterioration state.

In operation S420, the processor 100 may be configured to determine whether the phase transition section is reached in the dQ/dV profile.

The phase transition section may be set in advance and may be a section including a voltage that generates a peak. The entry voltage of the phase transition section may be a voltage which is smaller than the voltage that generates the peak, and the ending voltage of the phase transition section may be a voltage which is greater than the voltage that generates the peak. Alternatively, the phase transition section may be a voltage level from the voltage that generates a peak to a voltage which is provided with a specified margin.

In operation S430, when the voltage of the battery cell 10 reaches the phase transition section, the processor 100 may be configured for controlling the charger 80 to charge the battery 60 at a constant voltage.

For example, operation S430 may be a procedure performed when the voltage of the battery cell 10 reaches the first phase transition section Ph1. The voltage of the battery cell 10 may be the voltage of the battery cell 10 including the maximum voltage. That is, a first constant voltage charging section CV1 may be a procedure performed when the maximum cell voltage reaches the lowest voltage in the first phase transition section Ph1.

In the first constant voltage charging section CV1, the battery 60 may be charged with the first constant voltage, and the first constant voltage may be the maximum cell voltage obtained at the time point of entering the first constant voltage charging section CV1 and may be the lowest voltage in the first phase transition section Ph1.

The reason for checking the maximum cell voltage as an entry condition for the first constant voltage charging section CV1 may be to prevent deterioration of the battery cell 10 with high resistance from being accelerated. The battery cell 10 with the maximum cell voltage may be estimated to include a large internal resistance. According to an exemplary embodiment of the present disclosure, to prevent further deterioration of the battery cell 10 with high internal resistance, constant voltage charging may be performed when the maximum cell voltage reaches the phase transition section, and the charging current of the battery cell 10 including the maximum cell voltage in the phase transition section may be reduced.

According to the exemplary embodiments of the present disclosure, by slightly lowering the charging speed in the section where the materials of the battery cell 10 are phase changed, side reactions may be reduced and durability of the battery cell 10 may be improved.

Furthermore, the processor 100 may charge the battery 60 again in a constant current scheme after the phase transition section. For example, the charging scheme of the battery 60 may be to enter a second constant current charging section CV2 after the first constant voltage charging section CV1. The end of the first constant voltage charging section CV1 may be the timing when the maximum cell voltage reaches the maximum voltage in the first phase transition section Ph1.

To enter the second constant current charging section CC2, the processor 100 may check the current of the battery 60 at the end timing of the phase transition section. The processor 100 may be configured to determine the charging current of the second constant current charging section CC2 based on a cutoff current Ass at the end timing in the first phase transition section Ph1. For example, the processor 100 may be configured to determine the size of a second constant current A2 within a range which is greater than or equal to a cut-off current A11 in the first phase transition section Ph1 and less than or equal to the first constant current A1.

In the present manner, the processor 100 may alternately perform constant current charging and constant voltage charging.

For example, a second constant voltage charging section CV2 may start when the voltage of the battery cell 10 reaches the second phase transition section Ph2. When the second phase transition section Ph2 ends, the processor 100 may charge the battery 60 based on a third constant current A3 in a third constant current charging section CC3. The third constant current A3 may be determined within a range which is greater than or equal to a second cut-off current A21 and less than or equal to the second constant current A2.

Furthermore, a third constant voltage charging section CV3 may start when the voltage of the battery cell 10 reaches the third phase transition section Ph3. When the third phase transition section Ph3 ends, the processor 100 may charge the battery 60 based on a fourth constant current A4 in a fourth constant current charging section CC4. The fourth constant current A4 may be determined within a range which is greater than or equal to a third cut-off current A31 and less than or equal to the third constant current A3.

Furthermore, a fourth constant voltage charging section CV4 may start when the voltage of the battery cell 10 reaches the fourth phase transition section Ph4.

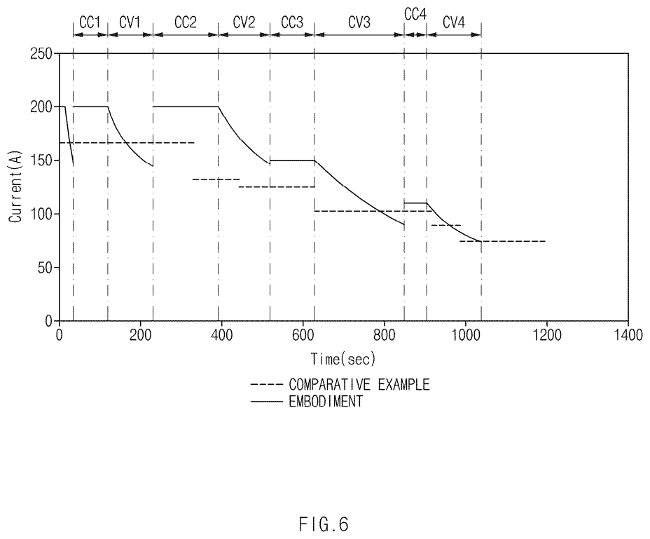

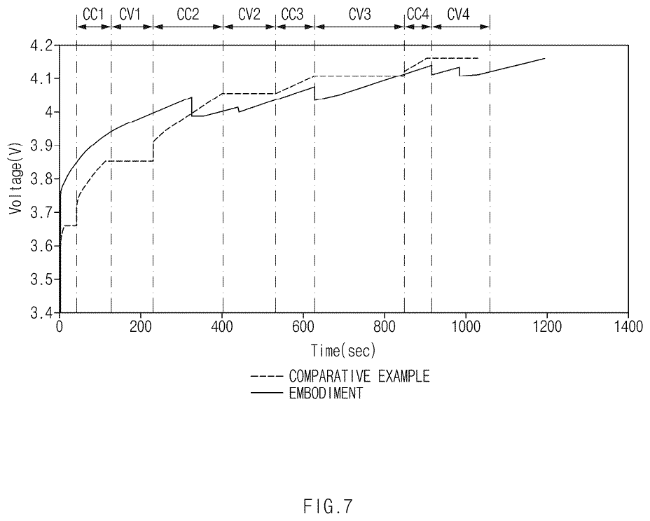

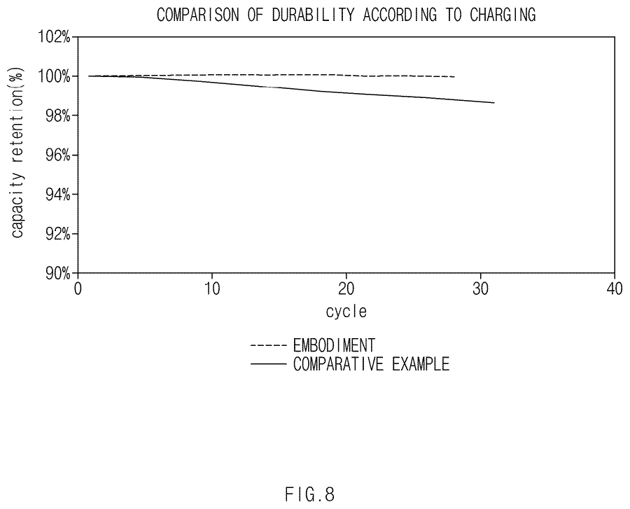

FIG. 6 is a diagram illustrating the current change of the battery cell during a battery charging process according to an exemplary embodiment of the present disclosure. FIG. 7 is a diagram illustrating the voltage change of a battery cell during a battery charging process according to an exemplary embodiment of the present disclosure. FIG. 8 is a diagram illustrating the change in durability of a battery cell according to an exemplary embodiment of the present disclosure. FIG. 6, FIG. 7, and FIG. 8 illustrate embodiments of the present disclosure together with comparative examples.

Referring to FIG. 6 and FIG. 7, according to an exemplary embodiment of the present disclosure, the battery 60 may be charged based on a constant current in the constant current charging sections CC1, CC2, CC3, and CC4, and the battery 60 may be charged based on a constant voltage in the constant voltage charging sections CV1, CV2, CV3, and CV4.

Because the battery 60 is charged at a constant voltage in the constant voltage charging sections CV1, CV2, CV3, and CV4, the charging current may be lowered and the charging speed may also be lowered.

Because the constant voltage charging sections CV1, CV2, CV3, and CV4 are sections where the internal materials of the battery 60 are phase-changed, side reactions may be active and the durability of the battery cell 10 may deteriorate. According to an exemplary embodiment of the present disclosure, side reactions may be suppressed while slightly lowering the charging speed of the battery 60 in the phase transition sections Ph1, Ph2, Ph3, and Ph4, improving the durability of the battery cell 10.

Furthermore, according to an exemplary embodiment of the present disclosure, because the charging current in the constant current charging period is determined to be more than the current value at the end of the previous constant voltage charging period, the battery 60 may be charged with a higher charging current than in the charging scheme of the comparative example. That is, during the constant current charging period, the slightly lowered charging speed during the constant voltage charging period may be compensated.

As shown in FIG. 8, according to an exemplary embodiment of the present disclosure, the charging capacity of the battery 60 may be maintained predetermined even when the cycle of charging the battery 60 is repeated.

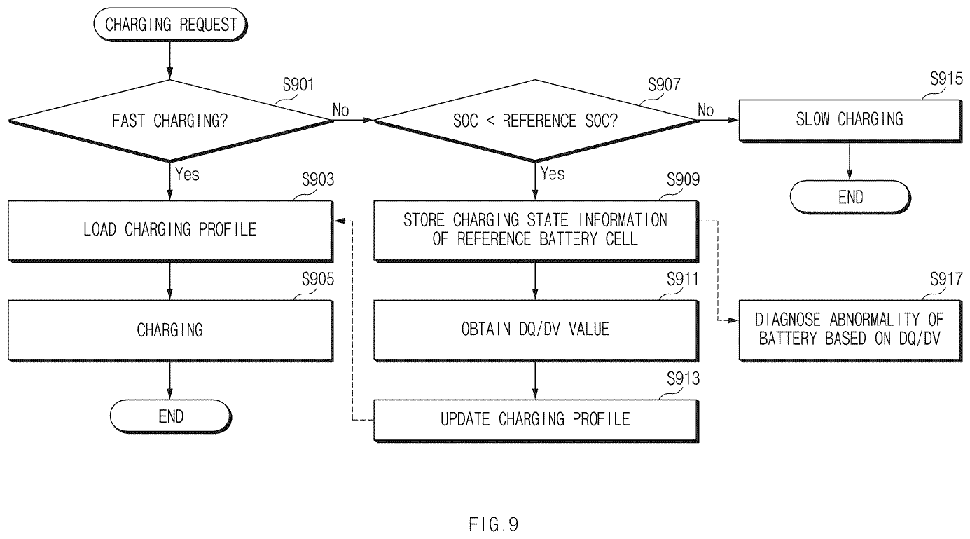

FIG. 9 is a flowchart illustrating a method of managing a battery according to another exemplary embodiment of the present disclosure. FIG. 9 may illustrate procedures controlled by the processor shown in FIG. 2. Hereinafter, a method of managing a battery according to an exemplary embodiment of the present disclosure will be described with reference to FIG. 9.

In operation S901, when there is a charging request, the processor 100 may be configured to determine whether the charging request is a fast charging request or a slow charging request.

In operation S903, in response to the fast charging request, the processor 100 may load a charging profile.

As shown in FIG. 5, the charging profile may include entry conditions for the constant current charging sections CC1, CC2, CC3, and CC4 and the constant voltage charging sections CV1, CV2, CV3, and CV4. For example, the charging profile may include voltage levels determined in each of the phase transition sections Ph1, Ph2, Ph3, and Ph4 to enter the constant voltage charging sections CV1, CV2, CV3, and CV4.

The charging profile may be determined based on the dQ/dV profile of the battery cell 10 shown in FIG. 3.

In operation S905, the processor 100 may charge the battery 60 by controlling the first charger 80 based on the charging profile.

In operations S901 and S907, in response to the charging request being a slow charging request, the processor 100 may be configured to determine whether an SOC value of the battery 60 is less than a reference SOC.

In operation S909, in response to the fact that the SOC value of the battery 60 is less than the reference SOC value, the charge state information of a reference battery cell may be stored. The reference battery cell may be the battery cell 10 representing the maximum cell voltage. The charge state information, which is used to obtain the dQ/dV profile, may include voltage information and charging capacity information.

In operation S911, the processor 100 may obtain the reference dQ/dV profile based on the charge state information of the reference battery cell.

For example, the processor 100 may obtain the reference dQ/dV profile by matching the voltage of the reference battery cell with a value obtained by differentiating the charging capacity of the reference battery cell by voltage.

In operation S913, the processor 100 may update the charging profile based on the reference dQ/dV profile.

The update of the charging profile may include a procedure for resetting the constant current charging section based on the peak of the reference dQ/dV profile. For example, the processor 100 may reset the constant current charging section when the difference between the voltage at which the peak of the reference dQ/dV profile occurs and the voltage at which the peak of the preset dQ/dV profile occurs is greater than or equal to the threshold voltage.

In operation S915, the processor 100 may perform slow charging based on the fact that the SOC value of the battery 60 is greater than or equal to the reference SOC.

Operation S915 may include a procedure of skipping operations S909 to S911. That is, based on the fact that the SOC value of the battery 60 is greater than or equal to the reference SOC value, the processor 100 may omit the procedure for updating the charging profile.

As a result, operation S913 of updating the charging profile excludes the case where the battery 60 is rapidly charged or the case where the SOC value of the battery 60 is greater than or equal to the reference SOC. This is because the peak of the phase transition section may be obtained more clearly when the SOC value of the battery 60 is low and the battery 60 is charged at a low charge rate (C-rate). Accordingly, the reference SOC may be determined below a level at which the peak of the phase transition section may be more clearly obtained.

In operation S917, the processor 100 may further perform a procedure of diagnosing whether the battery 60 is abnormal based on the reference dQ/dV profile.

For example, the processor 100 may diagnose whether the battery 60 is abnormal based on the reference dQ/dV profile and the average dQ/dV profile of the battery 60.

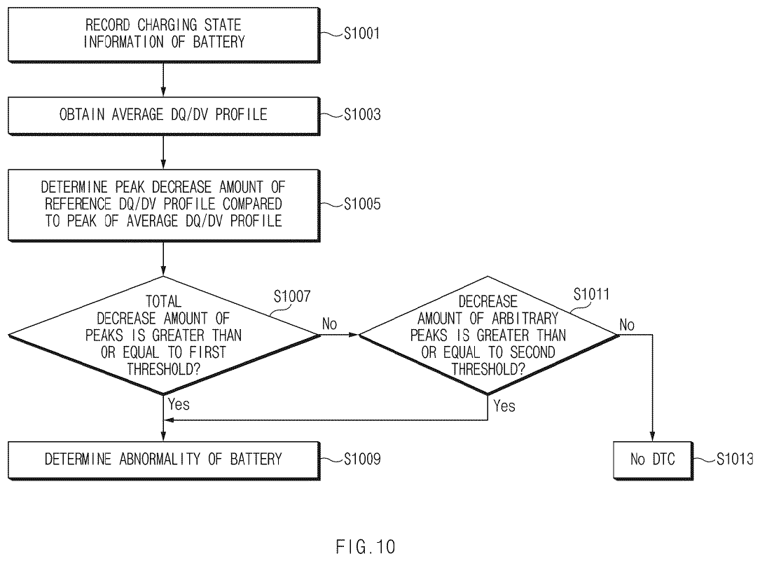

The detailed procedure of operation S917 will be explained based on FIG. 10 below.

FIG. 10 is a flowchart illustrating a method of diagnosing an abnormality of a battery according to an exemplary embodiment of the present disclosure.

Referring to FIG. 10, in operation S1001, the processor 100 may record the voltage of the battery 60 and the charging capacity of the battery 60.

In operation S1003, the processor 100 may obtain an average dQ/dV profile of the battery cell 10 based on the voltage of the battery 60 and the charging capacity of the battery 60. The average dQ/dV profile may be obtained based on the average cell voltage and average charge capacity.

In operation S1005, the processor 100 may be configured to determine the decrease amount of the peaks of the reference dQ/dV profile compared to the peaks of the average dQ/dV profile.

An example of determining the decrease amount of the peaks in the dQ/dV profile will be described based on following Table 1 below.

The following Table 1 illustrates the decrease amount of the peaks of the reference dQ/dV profile compared to the average dQ/dV profile.

TABLE 1

| | | | | |
|---|---|---|---|---|
| Peak in average | Pk1a | Pk2a | Pk3a | Pk4a |
| dQ/dV profile | | | | |
| Peak in | Pk1r | Pk2r | Pk3r | Pk4r |
| reference | | | | |
| dQ/dV profile | | | | |
| Peak decrease | Pk1a − Pk1r | Pk2a − Pk2r | Pk3a − Pk3r | Pk4a − Pk4r |
| amount | | | | |

In Table 1, Pk1a may be a peak in the first phase transition section of the average dQ/dV profile. Pk2a may be a peak in the second phase transition section of the average dQ/dV profile. Pk3a may be a peak in the third phase transition section of the average dQ/dV profile. Pk4a may be a peak in the fourth phase transition section of the average dQ/dV profile.

Pk1r may be a peak in the first phase transition section of the reference dQ/dV profile. Pk2r may be a peak in the second phase transition section of the reference dQ/dV profile. Pk3r may be a peak in the third phase transition section of the reference dQ/dV profile. Pk4r may be a peak in the fourth phase transition section of the reference dQ/dV profile.

The peak decrease amount may be the peak decrease amount in each phase transition section. For example, the first peak decrease amount may be obtained by subtracting the peak in the first phase transition section of the reference dQ/dV profile from the peak in the first phase transition section of the average dQ/dV profile. That is, the processor 100 may be configured to determine Pk1a-Pk1r and obtain the first peak decrease amount. Similarly, the processor 100 may obtain a second peak decrease amount based on Pk2a to Pk2r, a third peak decrease amount based on Pk3a to Pk3r, and a fourth peak decrease amount based on Pk4a to Pk4r.

In operations S1007 and S1009, the processor 100 may be configured to determine that the battery 60 is defective based on the fact that the total amount of decrease in peaks is greater than or equal to the first threshold.

For example, the processor 100 may be configured to determine that the battery 60 is abnormal based on the fact that the sum of the first peak decrease amount, the second peak decrease amount, the third peak decrease amount, and the fourth peak decrease amount is greater than or equal to the first threshold. The processor 100 may be configured to determine that a large amount of active material in the battery is lost overall when the sum of the peak amounts decreases beyond a specified level.

In operation S1011, the processor 100 may be configured to determine that the battery 60 is abnormal based on the fact that at least one decrease amount among the peak decrease amounts is greater than or equal to the second threshold.

For example, the processor 100 may be configured to determine that a state in which the first peak decrease amount is reduced by a specified level or more is a state in which the deformation and loss of the negative electrode active material is greater than that of the positive electrode active material.

Furthermore, the processor 100 may be configured to determine that oxygen detachment from the positive active material occurs when the fourth peak decrease amount is reduced by a specified level or more. It may be determined that the fourth peak Pk4 appears forcibly in the NMC battery in a Ni abnormal state, and in a state where the amount of decrease in the fourth peak Pk4 is large, the oxygen detachment is strong to cause Li decay.

Furthermore, in addition to the exemplary embodiment shown in FIG. 10, based on the amount of change in voltages matching the peaks of the reference dQ/dV profile compared to the voltages matching the peaks of the average dQ/dV profile, the processor 100 may be configured to determine whether the battery 60 is abnormal.

To the present end, as shown in FIG. 3, the processor 100 may identify the first to fourth voltages V1, V2, V3, and V4, each of which causes a peak.

The processor 100 may be configured to determine whether the first voltage V1 in the reference dQ/dV profile is shifted compared to the first voltage V1 in the average dQ/dV profile. The processor 100 may be configured to determine that the battery 60 is abnormal when the first voltage V1 in the reference dQ/dV profile is greater than or equal to the third threshold compared to the first voltage V1 in the average dQ/dV profile. Likewise, when the second to fourth voltages V2, V3, and V4 in the reference dQ/dV profile are greater than or equal to the third threshold in comparison to each of the second to fourth voltages V2, V3, and V4 in the average dQ/dV profile, the processor 100 may be determined that the battery 60 is abnormal.

The processor 100 may be configured to determine that the ratio of the positive and negative electrodes of the battery 60 is misaligned when the voltage deviation that generates the peak is above a specified level. For example, when the irreversible Li increases inside the negative electrode, the negative electrode voltage may increase, so that the processor 100 may be configured to determine that the peak is shifted due to a shift of the negative electrode voltage.

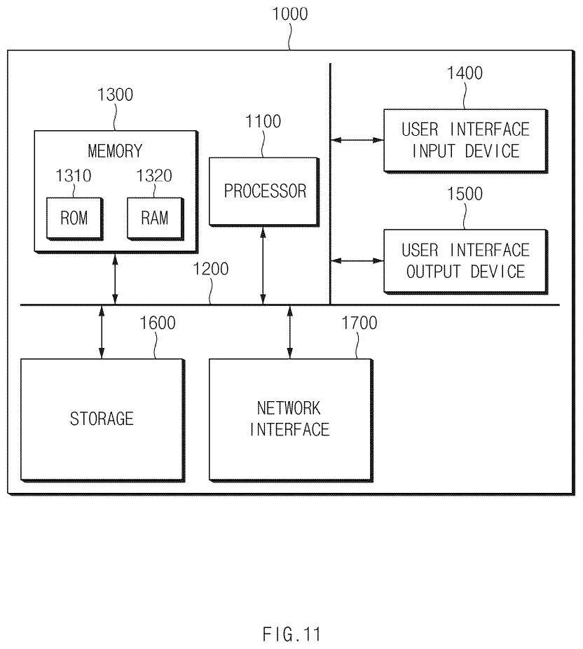

FIG. 11 is a block diagram illustrating a computing system according to an exemplary embodiment of the present disclosure.

Referring to FIG. 11, a computing system 1000 may include at least one processor 1100, a memory 1300, a user interface input device 1400, a user interface output device 1500, storage 1600, and a network interface 1700 connected through a bus 1200.

The processor 1100 may be a central processing unit (CPU) or a semiconductor device that processes instructions stored in the memory 1300 and/or the storage 1600. The memory 1300 and the storage 1600 may include various types of volatile or non-volatile storage media. For example, the memory 1300 may include a Read-Only Memory (ROM) and a Random Access Memory (RAM).

Accordingly, the processes of the method or algorithm described in relation to the exemplary embodiments of the present disclosure may be implemented directly by hardware executed by the processor 1100, a software module, or a combination thereof. The software module may reside in a storage medium (that is, the memory 1300 and/or the storage 1600), such as a RAM, a flash memory, a ROM, an EPROM, an EEPROM, a register, a hard disk, solid state drive (SSD), a detachable disk, or a CD-ROM.

The exemplary storage medium is coupled to the processor 1100, and the processor 1100 may read information from the storage medium and may write information in the storage medium. In another method, the storage medium may be integrated with the processor 1100. The processor and the storage medium may reside in an application specific integrated circuit (ASIC). The ASIC may reside in a user terminal. In another method, the processor and the storage medium may reside in the user terminal as an individual component.

According to the exemplary embodiments of the present disclosure, by reducing side reactions in the phase change section of the material inside the battery, it is possible to reduce the cause of deteriorating durability during the battery charging process.

Furthermore, according to the exemplary embodiments of the present disclosure, it is possible to diagnose an abnormal state of a battery based on the dQ/dV profile according to battery charging.

Furthermore, various effects that are directly or indirectly understood through the present disclosure may be provided.

Although exemplary embodiments of the present disclosure have been described for illustrative purposes, those skilled in the art will appreciate that various modifications, additions and substitutions are possible, without departing from the scope and spirit of the present disclosure.

Furthermore, the terms such as “unit”, “module”, etc. included in the specification mean units for processing at least one function or operation, which may be implemented by hardware, software, or a combination thereof.

In the flowchart described with reference to the drawings, the flowchart may be performed by the controller or the processor. The order of operations in the flowchart may be changed, multiple operations may be merged, or any operation may be divided, and a specific operation may not be performed. Furthermore, the operations in the flowchart may be performed sequentially, but not necessarily performed sequentially. For example, the order of the operations may be changed, and at least two operations may be performed in parallel.

Hereinafter, the fact that pieces of hardware are coupled operably may include the fact that a direct and/or indirect connection between the pieces of hardware is established by wired and/or wirelessly.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the present specification, unless stated otherwise, a singular expression includes a plural expression unless the context clearly indicates otherwise.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. An apparatus for managing a battery, the apparatus comprising:
an charger configured to charge the battery including two or more battery cells connected in series; and
a processor operably connected to the charger and configured to:
control the charger to charge the battery with a first constant current in response to a fast charging request for the battery,
determine one of cell voltages of the two or more battery cells while fast charging is in progress, and
control charging characteristics of the battery according to a section in a dQ/dV profile to which the cell voltage belongs.

2. The apparatus of claim 1, wherein the processor is further configured to:
determine whether the cell voltage to be in a phase transition section of the dQ/dV profile in a section where the fast charging is in progress; and
control the charger to charge the battery at a constant voltage in the phase transition section.

3. The apparatus of claim 2, wherein the processor is further configured to determine a voltage section including the cell voltage corresponding to a peak in the dQ/dV profile as the phase transition section.

4. The apparatus of claim 2, wherein the processor is further configured to:
identify a maximum cell voltage at an entry timing of the phase transition section; and
determine the maximum cell voltage as a magnitude of the constant voltage.

5. The apparatus of claim 2, wherein the processor is further configured to control the charger to charge the battery based on a second constant current after the phase transition section.

6. The apparatus of claim 2, wherein the processor is further configured to:
identify a cut-off current corresponding to a current of the battery at an end timing of the phase transition section; and
determine a magnitude of an initial current after the phase transition section within a range greater than or equal to the cut-off current and less than to the first constant current.

7. The apparatus of claim 2, wherein the processor is further configured to:
determine a battery cell showing a maximum cell voltage in response to a slow charging request, among the two or more battery cells;
obtain a reference dQ/dV profile for the battery cell showing the maximum cell voltage; and
update the dQ/dV profile based on the reference dQ/dV profile.

8. The apparatus of claim 7, wherein the processor is further configured to exclude an update procedure of the phase transition section based on a determination that a remaining capacity of the battery is greater than a reference remaining capacity.

9. The apparatus of claim 7, wherein the processor is further configured to:
obtain the reference dQ/dV profile including a plurality of peaks;
obtain an average dQ/dV profile based on average voltages of the two or more battery cells; and
determine whether the battery is in an abnormal state based on a decrease amount of the peaks of the reference dQ/dV profile compared to peaks of the average dQ/dV profile.

10. The apparatus of claim 9, wherein the processor is further configured to determine that the battery is in the abnormal state based on a total decrease amount of the peaks of each reference dQ/dV profile compared to the peaks of each average dQ/dV profile being greater than or equal to a first threshold.

11. The apparatus of claim 9, wherein the processor is further configured to determine that the battery is in the abnormal state based on at least one of decrease amounts of the peaks of the reference dQ/dV profile compared to the peaks of the average dQ/dV profile being greater than or equal to a second threshold.

12. The apparatus of claim 9, wherein the processor is further configured to determine whether the battery is in the abnormal state based on voltages matching the peaks of the reference dQ/dV profile compared to voltages matching the peaks of the average dQ/dV profile.

13. A method of managing a battery, the method comprising:
controlling, by a processor, a charger operably connected to the processor to charge the battery with a first constant current in response to a fast charging request for the battery including a plurality of battery cells;
determining, by the processor, one of cell voltages of the battery cells while fast charging is in progress; and
controlling, by the processor, charging characteristics of the battery according to a section in a dQ/dV profile to which the cell voltage belongs.

14. The method of claim 13, wherein the controlling of the charging characteristics includes:
determining whether the cell voltage is included in a phase transition section of the dQ/dV profile; and
controlling the charger to charge the battery at a constant voltage in the phase transition section.

15. The method of claim 14, wherein the controlling of the charger in the phase transition section includes:
determining a maximum cell voltage at an entry timing of the phase transition section; and
determining the maximum cell voltage as a magnitude of the constant voltage.

16. The method of claim 14, further including:
charging the battery based on a second constant current after the phase transition section.

17. The method of claim 16, wherein the charging of the battery based on the second constant current includes:
identifying a cut-off current corresponding to a current of the battery at an end timing of the phase transition section; and
determining a magnitude of an initial current after the phase transition section within a range greater than or equal to the cut-off current and less than the first constant current.

18. The method of claim 13, further including:
identifying, by the processor, a battery cell showing a maximum cell voltage in response to a slow charging request, among the battery cells;
obtaining a reference dQ/dV profile for the battery cell showing the maximum cell voltage; and
updating the dQ/dV profile based on the reference dQ/dV profile.

19. The method of claim 18, further including:
detecting peaks in the reference dQ/dV profile;
obtaining an average dQ/dV profile based on average voltages of the battery cells; and
determining whether the battery is in an abnormal state based on a decrease amount of the peaks of the reference dQ/dV profile compared to peaks of the average dQ/dV profile.

20. The method of claim 19, wherein the determining of whether the battery is in the abnormal state includes determining whether the battery is in the abnormal state based on voltages matching the peaks of the reference dQ/dV profile compared to voltages matching the peaks of the average dQ/dV profile.
